(19) United States
(12) Patent Application Publication
(10) Pub. No.: US 2006/0282755 A1
(43) Pub. Date: Dec. 14, 2006

(54) Random access memory having ECC

(76) Inventor: Jong-Hoon Oh, Chapel Hill, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/141,154

(22) Filed: May 31, 2005

(51) Int. Cl. G06F 11/00; H03M 13/00

(52) U.S. Cl. 714/801

(57) ABSTRACT

A memory includes a memory array for storing data, a parity generation and error check circuit configured to receive data from the memory array and detect errors in the data, and error registers configured for storing addresses of failing memory array locations detected by the parity generation and error check circuit upon self refresh entry for correcting the data stored in the failing memory array locations upon self refresh exit.

### BACKGROUND

Memory speed and memory capacity continue to increase to meet the demands of system applications. Some of these system applications include mobile electronic systems that have limited space and limited power resources. In mobile applications, such as cellular telephones and personal digital assistants (PDAs), memory cell density and power consumption are issues for future generations. To address these issues, the industry is developing random access memories (RAMs) for mobile applications. For low power DRAMs, such as low power single data rate (LP-SDR) DRAMs, low power double data rate (LP-DDR) DRAMs, and low power double data rate II (LP-DDR2) DRAMs, reducing the refresh current is one way to reduce power consumption.

To reduce the refresh current, the refresh period is typically extended. Extending the refresh period, however, typically results in some memory cells failing due to the extended refresh period. For example, 99.9% of the memory cells in an array of memory cells may have a retention time of 250 ms. The other 0.1%, however, may fail to retain their values from anywhere between approximately 0-200 ms. These memory cells that fail to retain their values are referred to as tail bits. These tail bits may lead to single bit errors during self refresh of a memory. By detecting and correcting for these tail bits, the refresh period may be extended to reduce the refresh current.

Error correction code (ECC) calculates parity information and can determine if a bit has switched to an incorrect value. ECC can compare the parity originally calculated to the tested parity and make any corrections to correct for incorrect data values. In some cases, it is desirable to have ECC built directly onto a memory chip to provide greater memory chip reliability or to optimize other memory chip properties, such as self refresh currents on low power DRAMs. For typical DRAMs utilizing ECC, upon entry of self refresh, parity data is generated and written back to the memory. For example, for 1024 data bits, 16 parity bits are generated and written back to the memory. At self refresh exit, the 16 parity bits plus the 1024 data bits are read and the data bits are checked for errors and corrected based on the parity bits. The corrected data is written back to the memory. Typically, the user of the memory must wait while this error detection and correction process is performed for all memory cells within the memory array upon self refresh exit. The error correction process may delay self refresh exit from anywhere between approximately 10 ms-100 ms. This delay upon self refresh exit may affect the performance of the memory system.

### SUMMARY

One embodiment of the present invention provides a memory. The memory includes a memory array for storing data, a parity generation and error check circuit configured to receive data from the memory array and detect errors in the data, and error registers configured for storing addresses of failing memory array locations detected by the parity generation and error check circuit upon self refresh entry for correcting the data stored in the failing memory array locations upon self refresh exit.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a block diagram illustrating one embodiment of a random access memory, according to the present invention.

FIG. 2 is a timing diagram illustrating one embodiment of the timing of signals for generating parity information for a memory array upon self refresh entry.

FIG. 3 is a timing diagram illustrating one embodiment of the timing of signals for detecting and correcting errors in the memory array upon self refresh entry.

FIG. 4 is a timing diagram illustrating one embodiment of the timing of signals for rechecking and correcting errors in the memory array upon self refresh exit.

FIG. 5 is a block diagram illustrating another embodiment of a random access memory, according to the present invention.

FIG. 6 is a timing diagram illustrating one embodiment of the timing of signals for detecting errors in the memory array upon self refresh entry.

FIG. 7 is a timing diagram illustrating one embodiment of the timing of signals for correcting errors in the memory array upon self refresh exit.

FIG. 8 is a block diagram illustrating one embodiment of a portion of the random access memory including error registers for storing memory cell addresses and corrected data for use as replacement storage for failing memory cell locations.

FIG. 9 is a block diagram illustrating one embodiment of a portion of the random access memory including error registers for storing row addresses of tail bits for refreshing the tail bits more frequently.

### DETAILED DESCRIPTION

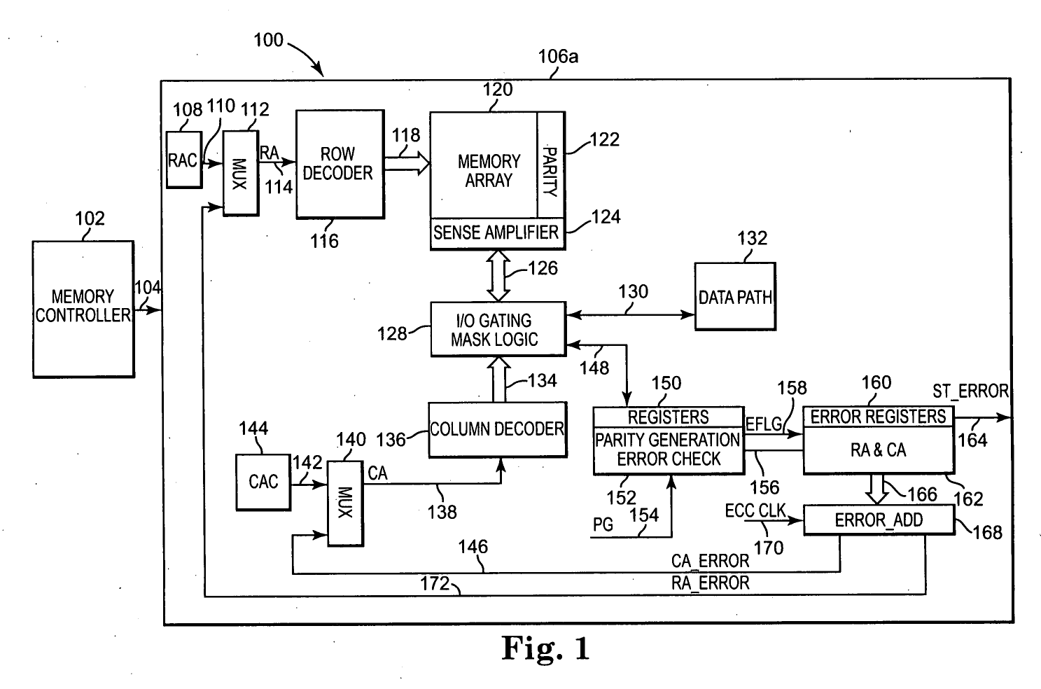

FIG. 1 is a block diagram illustrating one embodiment of a random access memory 100, according to the present invention. In one embodiment, random access memory 100 is a dynamic random access memory (DRAM). DRAM 100 includes a memory controller 102 and at least one memory bank 106a. Memory bank 106a includes row address counter (RAC) 108, multiplexer (MUX) 112, row decoder 116, memory array 120 including parity memory 122, sense amplifiers 124, and I/O gating mask logic 128. Memory bank 106a also includes data path 132, column decoder 136, multiplexer (MUX) 140, column address counter (CAC) 144, registers 150, parity generation and error check circuit 152, error registers 160 including row address (RA) and column address (CA) registers 162, and error address (ERROR_ADD) block 168. Memory controller 102 is electrically coupled to memory circuit 106a through communication link 104.

DRAM 100 is configured for an extended refresh period during self refresh to reduce the power consumption of DRAM 100. DRAM 100 performs an error detection and correction process during self refresh to correct tail bits without substantially interfering with the self refresh exit timing. DRAM 100 generates parity information for memory array 120 upon self refresh entry and stores the parity information in parity memory 122. After the first extended refresh period in self refresh has elapsed, memory array 120 is checked for errors using the stored parity information. In one embodiment, any errors detected are corrected and the locations of failing memory cells are stored in error registers 160. Upon self refresh exit, the locations of failing memory cells stored in error registers 160 are rechecked for errors and corrected if errors are detected. If there are no failing memory cell locations stored in error registers 160, then upon self refresh exit no recheck for errors is performed.

In another embodiment, in addition to the locations of failing memory cells, the corrected data for the failing memory cells is also stored in error registers 160. In this embodiment, upon self refresh exit, the corrected data is automatically written back to the failing memory cells without rechecking for errors.

In another embodiment, error registers 160 store locations of failing memory cells and the corrected data to replace failing memory cells, such as in a redundancy or single bit repair. In this embodiment, no write back operation is performed upon self refresh exit. A selected address is compared to the addresses stored in error registers 160. If a match is found, the corrected data stored in error registers 160 is passed to data path 132 in place of the data stored in the failing memory cells.

In another embodiment, error registers 160 store row addresses of tail bits. The row addresses stored in error registers 160 are compared to the row addresses from row address counter 108. If a match is found, the row is refreshed more frequently.

Memory controller 102 controls reading data from and writing data to memory bank 106a. Memory controller 102 provides row and column addresses and control signals to memory bank 106a through communication link 104. In one embodiment, memory controller 102 provides control signals including self refresh entry, self refresh exit, read/write enable, row address strobe (RAS), and column address strobe (CAS) signals.

Row address counter 108 is electrically coupled to a first input of multiplexer 112 through signal path 110. A second input of multiplexer 112 is electrically coupled to error address (ERROR_ADD) block 168 through row address error (RA_ERROR) signal path 172. The output of multiplexer 112 is electrically coupled to row decoder 116 through row address (RA) signal path 114. Row decoder 116 is electrically coupled to memory array 120 through row select lines 118. Memory array 120 is electrically coupled to sense amplifiers 124. Sense amplifiers 124 are electrically coupled to I/O gating mask logic 128 through data lines 126. I/O gating mask logic 128 is electrically coupled to data path 132 through data lines 130, registers 150 through data lines 148, and column decoder 136 through column select lines 134.

Column address counter 144 is electrically coupled to a first input of multiplexer (MUX) 140 through signal path 142. A second input of multiplexer 140 is electrically coupled to error address (ERROR_ADD) block 168 through column address error (CA_ERROR) signal path 146. The output of multiplexer 140 is electrically coupled to column decoder 136 through column address (CA) signal path 138. Registers 150 are electrically coupled to parity generation and error check circuit 152. Parity generation and error check circuit 152 is electrically coupled to error registers 160 through error flag (EFLG) signal path 158 and address signal path 156. Parity generation and error check circuit 152 also receives the parity generation (PG) signal on PG signal path 154. Error registers 160 are electrically coupled to error address block 168 through address lines 166. Error registers 160 also provide the status of error (ST_ERROR) signal on ST_ERROR signal path 164.

Row address counter 108 is configured to increment through each row address of memory array 120 for selecting each row of memory array 120 during parity information generation and parity error detection and correction processes upon self refresh entry. Multiplexer 112 is configured to pass either a row address provided by row address counter 108 during a parity information generation or parity error detection and correction process upon self refresh entry or pass a row address from error address block 168 for parity error detection and correction processes upon self refresh exit.

Row decoder 116 receives the row address on row address signal path 114 and activates a row in memory array 120 based on the received address. Memory array 120 includes a plurality of memory cells located at each cross point of a word line (row) and a bit line (column). Parity memory 122 is part of memory array 120 and stores the parity information for memory array 120. Sense amplifiers 124 sense the data bit values stored in the memory cells along the activated row during a read operation and write data bit values to the memory cells along the activated row during a write operation.

Column address counter 144 is configured to increment through each column address of memory array 120 for selecting each column of memory array 120 during parity information generation and parity error detection and correction processes upon self refresh entry. Multiplexer 140 is configured to pass either a column address provided by column address counter 144 during a parity information generation or parity error detection and correction process upon self refresh entry or pass a column address from error address block 168 for parity error detection and correction processes upon self refresh exit.

Column decoder 136 receives the column address on column address signal path 138 and activates the selected column select lines 134. Based on the selected column select lines 134, I/O gating mask logic 128 passes the selected data bit values on data lines 126 to data path 132 through data lines 130 if DRAM 100 is not in self refresh. Data path 132 includes data I/O pads or pins, referred to as DQs, for passing data between DRAM 100 and an external device, such as a host. If DRAM 100 is in self refresh, I/O gating mask logic 128 passes the selected data bit values on data lines 126 to registers 150 through data lines 148.

Registers 150 include data registers for temporarily storing data from memory array 120 and a parity register for temporarily storing the parity of the data in the data registers. In one embodiment, registers 150 include 64 data bit registers and corresponding parity bit registers. In one embodiment, parity generation and error check circuit 152 includes a plurality of exclusive OR (XOR) gates for determining the parity of the data bits stored in registers 150. Parity generation and error check circuit 152 receives the parity generation signal on parity generation signal path 154. In response to a logic high parity generation signal, parity generation and error check circuit 152 generates the parity information for the data bits stored in registers 150. Parity generation and error check circuit 150 then either stores the generated parity information in the parity registers of registers 150 or compares the generated parity information to previously generated parity information stored in the parity registers of registers 150. If the generated parity information does not match the previously stored parity information, parity generation and error check circuit 152 provides an error flag signal on error flag signal path 158 and the address of the failed memory array location on signal path 156.

Error registers 160 receive the error flag signal on error flag signal path 158 and the addresses of failed memory array locations on signal path 156 and provide the ST_ERROR signal on ST_ERROR signal path 164. The ST_ERROR signal is logic low with no addresses of failed memory array locations stored in error registers 160 to indicate the rechecking for errors process at self refresh exit can be skipped. The ST_ERROR signal is logic high with addresses of failed memory array locations stored in error registers 160 to indicate that the failed memory array locations are to be rechecked for errors upon self refresh exit.

The row addresses and column addresses for failing memory array locations are stored in row address and column address registers 162. The row addresses and column addresses for failing memory array locations are passed to error address block 168 upon self refresh exit. Upon self refresh exit, the row addresses and column addresses for failing memory array locations are clocked out by the error correction clock (ECC_CLK) signal on ECC_CLK signal path 170 to provide the CA_ERROR signal on CA_ERROR signal path 146 and the RA_ERROR signal on RA_ERROR signal path 172. The RA_ERROR signal and the CA_ERROR signal are used to recheck the failing memory array locations in memory array 120 for parity errors and correct any errors detected.

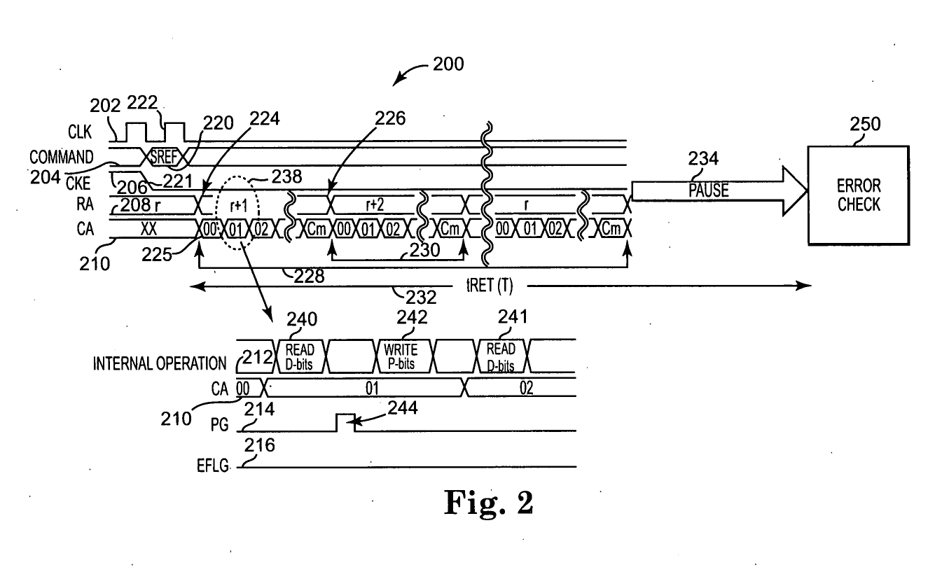

FIG. 2 is a timing diagram 200 illustrating one embodiment of the timing of signals for generating parity information for memory array 120 upon self refresh entry. Timing diagram 200 includes a clock signal (CLK) signal 202, a command signal 204, a clock enable (CKE) signal 206, row address (RA) signal 208 on RA signal path 114, and column address (CA) signal 210 on CA signal path 138. Timing diagram 200 also includes a detail portion as indicated at 238 that includes an internal operation signal 212, column address (CA) signal 210, parity generation (PG) signal 214 on PG signal path 154, and error flag (EFLG) signal 216 on EFLG signal path 158. In one embodiment, CLK signal 202, command signal 204, CKE signal 206, internal operation signal 212, and PG signal 214 are provided by memory controller 102.

Memory controller 102 provides a self refresh (SREF) command at 220 on command signal 204. In response to the self refresh command, CKE signal 206 transitions to logic low at 221. In response to rising edge 222 of CLK signal 202, self refresh is initiated. Row address counter 108 provides row address ‘R+1’ on RA signal 208 at 224. At 224, row ‘R+1’ is activated by row decoder 116. Column address counter 144 provides column address ‘00’ on CA signal 210 at 225. Row address counter 108 increments through each row address of memory array 120 on RA signal 208 as indicated at 228. For each row address, column address counter 144 increments through each column address of memory array 120 on CA signal 210 as indicated at 230. Before each row address change, such as the row address change indicated at 226, memory array 120 is precharged.

The operations performed at each row address and column address are indicated in the detail portion indicated at 238. For each row address and column address, memory controller 102 provides a read data command at 240 on internal operation signal 212. A set number of data bits, such as 64 bits, are read from memory array 120 at the selected row address and the selected column address (row address ‘R+1’ and column address ‘01’ in this example). Memory controller 102 provides a parity generation pulse on PG signal 214 at 244 to parity generation and error check circuit 152. In response to the parity generation pulse at 244, parity generation and error check circuit 152 generates the parity information for the read data bits, such as the 64 bits. At 242, memory controller 102 provides a write parity bits command on internal operation signal 212 to write the parity information to parity memory 122. At 241, the parity generation process repeats for the next column address (‘02’).

The parity generation process continues until the parity information for the entire memory array 120 is generated and stored in parity memory 122. After generating the parity information for the entire memory array 120, memory operations are paused as indicated at 234 until the completion of the extended refresh period (tRET) as indicated at 232. After the extended refresh period 232 has elapsed, memory array 120 is checked for errors as indicated by block 250.

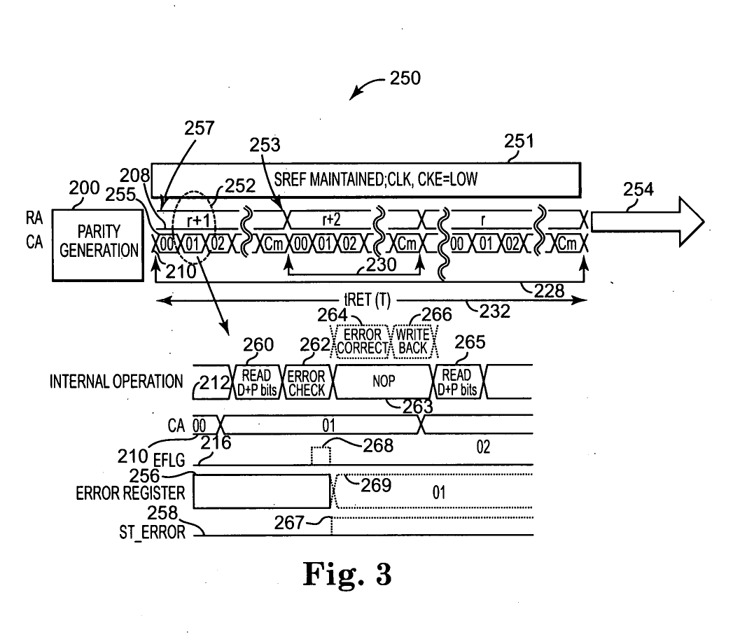

FIG. 3 illustrates a timing diagram 250 illustrating one embodiment of the timing of signals for detecting and correcting errors in memory array 120 upon self refresh entry. Timing diagram 250 includes RA signal 208 and CA signal 210. Timing diagram 250 also includes a detail portion as indicated at 252 that includes internal operation signal 212, CA signal 210, EFLG signal 216, error register signal 256, and ST_ERROR signal 258 on ST_ERROR signal path 164. Parity generation as indicated by block 200 was previously performed as illustrated and described with reference to FIG. 2. Self refresh is maintained by command signal 204 and CLK signal 202 and CKE signal 206 remain logic low as indicated by block 251.

In response to the extended refresh period 232 elapsing, error checking of memory array 120 is initiated. Row address counter 108 provides row address ‘R+1’ on RA signal 208 at 257. At 257, row ‘R+1’ is activated by row decoder 116. Column address counter 144 provides column address ‘00’ on CA signal 210 at 255. Row address counter 108 increments through each row address of memory array 120 on RA signal 208 as indicated at 228. For each row address, column address counter 144 increments through each column address of memory array 120 on CA signal 210 as indicated at 230. Before each row address change, such as the row address change indicated at 253, memory array 120 is precharged.

The operations performed at each row address and column address are indicated in the detail portion indicated at 252. For each row address and column address, memory controller 102 provides a read data and parity bits command at 260 on internal operation signal 212. A set number of data bits, such as 64 bits, and the corresponding parity bits are read from memory array 120 and parity memory 122 at the selected row address and the selected column address (row address ‘R+1’ and column address ‘01’ in this example). Memory controller 102 provides an error check command at 262 on internal operation signal 212. In response to the error check command, parity generation and error check circuit 152 checks for errors in the read data based on the corresponding read parity bits.

If no errors are detected, parity generation and error check circuit 152 provides a logic low EFLG signal 216. If a parity error or errors are detected, parity generation and error check circuit 152 provides a logic high EFLG signal at 268. In response to a logic low EFLG signal indicating no errors, memory controller 102 provides a no operation (NOP) command on internal operation signal 212 at 263. In response to a logic high EFLG signal indicating an error or errors, memory controller 102 provides an error correct command at 264 on internal operation signal 212. In response to the error correct command at 264, parity generation and error check circuit 152 corrects the errors. After the errors are corrected, memory controller 102 provides a write back command at 266 on internal operation signal 212. In response to write back command 266, the corrected data is written back to memory array 120.

In response to a logic high EFLG signal 216 at 268, the row address and column address where the error was detected is also written to error registers 160 as indicated at 269 on error register signal 256. Also in response to a logic high EFLG signal 216 at 268, error registers 160 provide a logic high ST_ERROR signal 258 at 267. At 265, the error checking process repeats for the next column address (‘02’).

The error checking process continues until the entire memory array 120 has been checked for errors and corrected if errors are detected. After checking the entire memory array 120 for errors and correcting any detected errors, self refresh continues as indicated at 254.

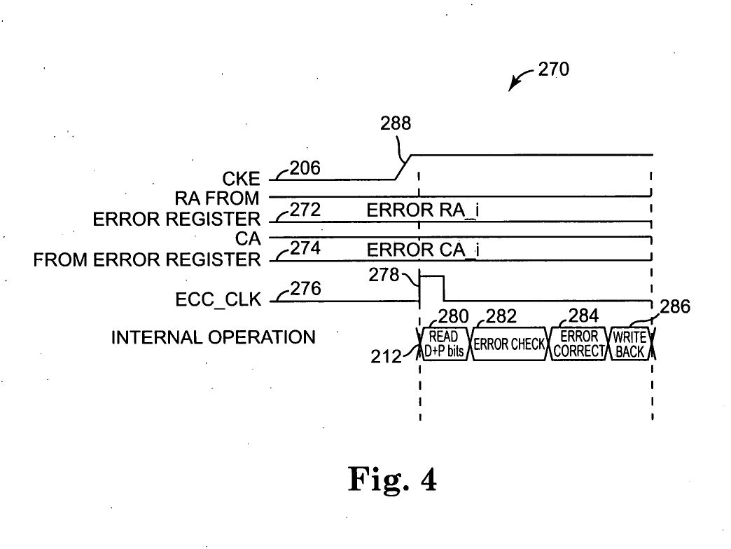

FIG. 4 is a timing diagram 270 illustrating one embodiment of the timing of signals for rechecking and correcting errors in memory array 120 upon self refresh exit. Timing diagram 270 includes CLE signal 206, RA signal 272 and CA signal 274 on signal path 166, ECC_CLK signal 276 on ECC_CLK signal path 170, and internal operation signal 212.

CKE signal 206 transitions to logic high at 288 indicating self refresh exit. Upon self refresh exit, ECC_CLK signal 276 clocks out each row address and column address stored in row address and column address registers 162 as indicated at 278. For each row address and column address, memory controller 102 provides a read data bits and corresponding parity bits command at 280 on internal operation signal 212. At 282, memory controller 102 provides an error check command on internal operation signal 212. In response to the error check command, parity generation and error check circuit 152 checks the read data bits for errors based on the corresponding read parity bits. At 284, memory controller 102 provides an error correct command. In response to the error correct command at 284, parity generation and error check circuit 152 corrects the errors. After the errors are corrected, memory controller 102 provides a write back command at 286 on internal operation signal 212. In response to the write back command at 286, the corrected data is written back to memory array 120. The self refresh exit time depends on the number of errors and the size of error registers 160. In one embodiment, the error detection and correction process is performed upon self refresh exit in approximately 100 ns-1 μs.

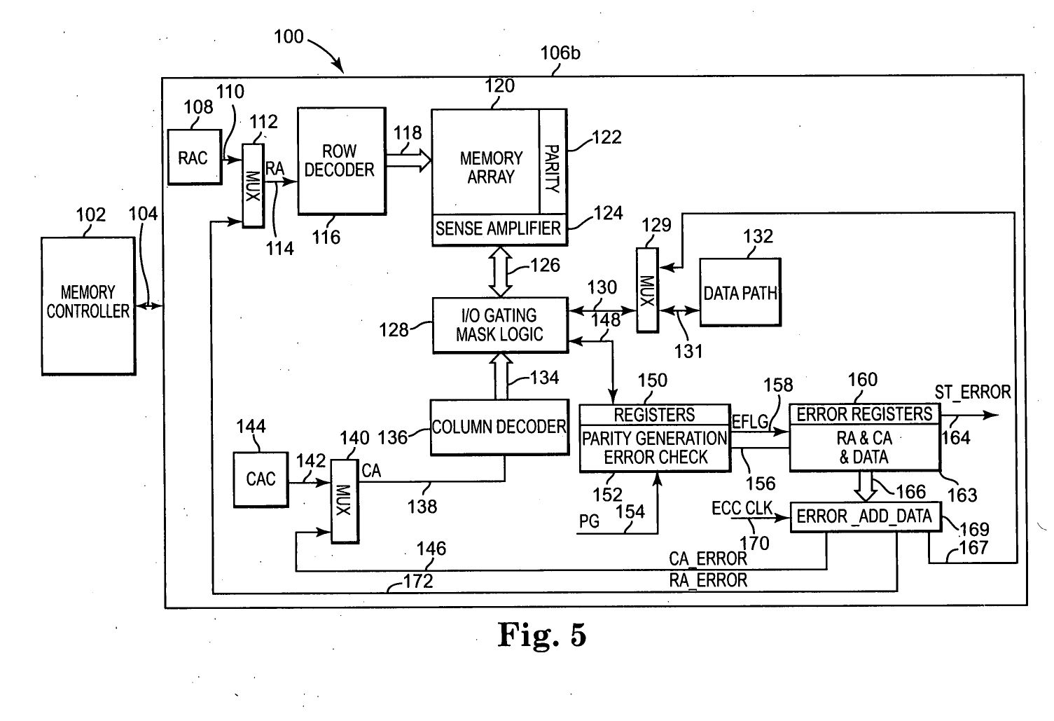

FIG. 5 is a block diagram illustrating another embodiment of a random access memory 100, according to the present invention. In one embodiment, random access memory 100 is a DRAM. DRAM 100 includes a memory controller 102 and at least one memory bank 106b. Memory bank 106b includes similar components as memory bank 106a as previously described and illustrated with reference to FIG. 1 except for the differences described below. Memory bank 106b includes row address counter (RAC) 108, multiplexer 112, row decoder 116, memory array 120 including parity memory 122, sense amplifiers 124, and I/O gating mask logic 128. Memory bank 106 also includes data path 132, column decoder 136, multiplexer 140, column address counter (CAC) 144, registers 150, parity generation and error check circuit 152, error registers 160 including row address (RA), column address (CA), and data registers 163, error address and data (ERROR_ADD_DATA) block 169, and multiplexer (MUX) 129.

An input of multiplexer 129 is electrically coupled to error address and data block 169 through data lines 167. A input/output of multiplexer 129 is electrically coupled to I/O gating mask logic 128 through data lines 130. An input/output of multiplexer 129 is electrically coupled to data path 132 through data lines 131. Multiplexer 129 is configured to pass data between I/O gating mask logic 128 and data path 132 during normal read and write operations and pass corrected data from error address and data block 169 to I/O gating mask logic 128 for failing memory array locations upon self refresh exit.

In this embodiment, error registers 160 receive the error flag signal on error flag signal path 158 and the addresses of failed memory array locations and the corrected data for the failed memory array locations on signal path 156 and provide the ST_ERROR signal on ST_ERROR signal path 164. The row addresses, column addresses, and corrected data for failing memory array locations are stored in row address, column address, and data registers 163. Upon self refresh exit, the corrected data for the failing memory array locations stored in error registers 160 is written back to the failing memory array locations in memory array 120 without first rechecking for errors at the failing memory array locations.

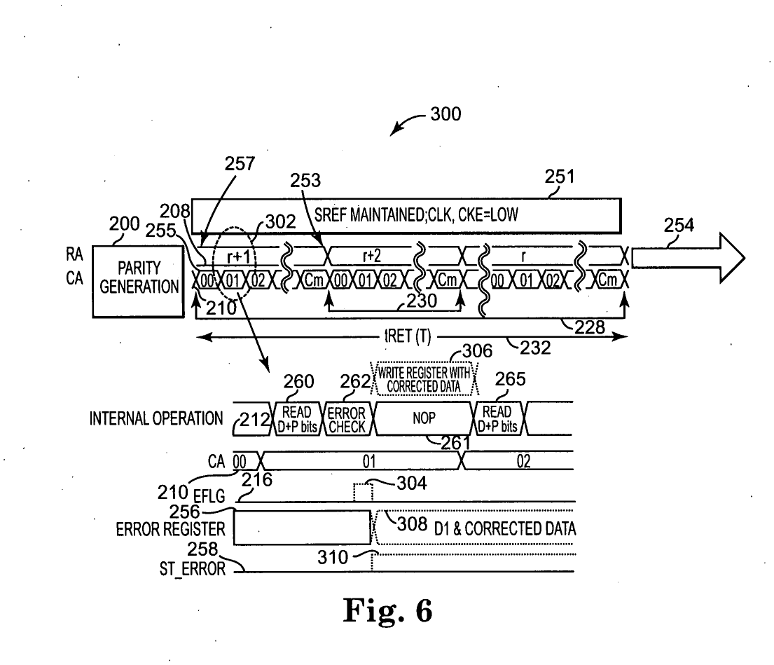

FIG. 6 illustrates a timing diagram 300 illustrating one embodiment of the timing of signals for detecting errors in memory array 120 upon self refresh entry. Timing diagram 300 includes RA signal 208 and CA signal 210. Timing diagram 300 also includes a detail portion as indicated at 302 that includes internal operation signal 212, CA signal 210, EFLG signal 216, error register signal 256, and ST_ERROR signal 258 on ST_ERROR signal path 164. Parity generation as indicated by block 200 is previously performed as illustrated and described with reference to FIG. 2. Self refresh is maintained by command signal 204 and CLK signal 202 and CKE signal 206 remain logic low as indicated by block 251.

In response to the extended refresh period 232 elapsing, error checking of memory array 120 is initiated. Row address counter 108 provides row address ‘R+1’ on RA signal 208 at 257. At 257, row ‘R+1’ is activated by row decoder 116. Column address counter 144 provides column address ‘00’ on CA signal 210 at 255. Row address counter 108 increments through each row address of memory array 120 on RA signal 208 as indicated at 228. For each row address, column address counter 144 increments through each column address of memory array 120 on CA signal 210 as indicated at 230. Before each row address change, such as the row address change indicated at 253, memory array 120 is precharged.

The operations performed at each row address and column address are indicated in the detail portion indicated at 302. For each row address and column address, memory controller 102 provides a read data and parity bits command at 260 on internal operation signal 212. A set number of data bits, such as 64 bits, and the corresponding parity bits are read from memory array 120 and parity memory 122 at the selected row address and the selected column address (row address ‘R+1’ and column address ‘01’ in this example). Memory controller 102 provides an error check command at 262 on internal operation signal 212. In response to the error check command, parity generation and error check circuit 152 checks for errors in the read data based on the corresponding read parity bits.

If no errors are detected, parity generation and error check circuit 152 provides a logic low EFLG signal 216. If a parity error or errors are detected, parity generation and error check circuit 152 provides a logic high EFLG signal 216 at 304. In response to a logic low EFLG signal indicating no errors, memory controller 102 provides a no operation (NOP) command on internal operation signal 212 at 261. In response to a logic high EFLG signal 216 at 304 indicating an error or errors, memory controller 102 provides a write register with corrected data command at 306 on internal operation signal 212. In response to the write register with corrected data command at 306, parity generation and error check circuit 152 corrects the errors and writes the corrected data and the row address and column address where the error was detected to error registers 160 as indicated at 308 on error register signal 256. Also in response to the logic high EFLG signal 216 at 304, error registers 160 provide a logic high ST_ERROR signal 258 at 310. At 265, the error checking process repeats for the next column address (‘02’).

The error checking process continues until the entire memory array 120 has been checked for errors and corrected data written to error registers 160 if errors are detected. After checking the entire memory array 120 for errors, self refresh continues as indicated at 254.

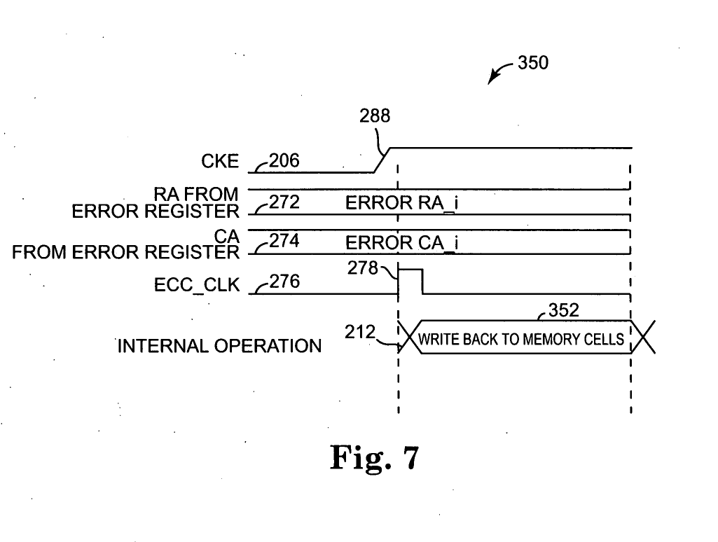

FIG. 7 is a timing diagram 350 illustrating one embodiment of the timing of signals for correcting errors in memory array 120 upon self refresh exit. Timing diagram 350 includes CKE signal 206, RA signal 272, CA signal 274, ECC_CLK signal 276, and internal operation signal 212.

CKE signal 206 transitions to logic high at 288 indicating self refresh exit. Upon self refresh exit, ECC_CLK signal 276 clocks out each row address, column address, and corrected data stored in row address, column address, and data registers 163, as indicated at 278. For each row address and column address, memory controller 102 provides a write back to memory cells command at 352 on internal operation signal 212. In response to the write back to memory cells command at 352, the corrected data is written back to memory array 120. The self refresh exit time depends on the number of errors and the size of error registers 160. In one embodiment, the error correction process is performed upon self refresh exit in approximately 100 ns-1 μs.

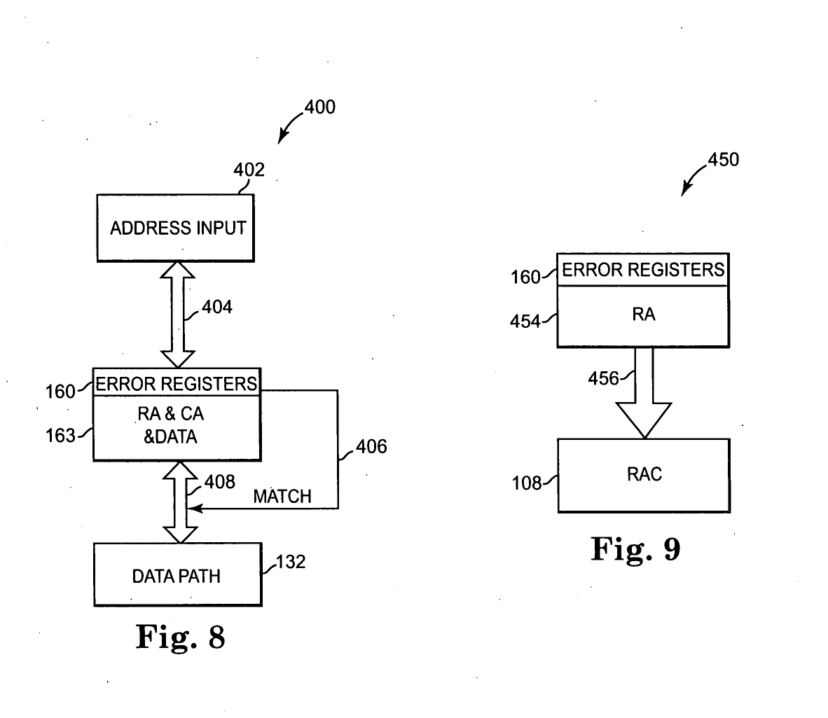

FIG. 8 is a block diagram illustrating one embodiment of a portion 400 of DRAM 100 including error registers 160 for storing memory array addresses and corrected data for use as replacement storage for failing memory array locations. This is similar to a redundancy or single bit repair. In this embodiment, the error detection process performed upon self refresh entry as previously described and illustrated with reference to FIG. 6 is performed. Upon self refresh exit, however, no write back operation is performed.

Portion 400 includes address input block 402, error registers 160 including row address, column address, and data registers 163, and data path 132. Address input block 402 is electrically coupled to error registers 160 through signal path 404. Address input block 403 provides a row address and column address for reading data from or writing data to memory array 120. Error registers 160 are electrically coupled to data path 132 through data lines 408. A match signal on match signal path 406 enables data lines 408 to pass data to data path 132 or disables data lines 408 to block data from passing to data path 132.

In operation, after self refresh exit, the address input in address block 402, which is provided by memory controller 102, is compared with addresses stored in error registers 160. If a match is found, the corrected data stored in data registers 163 is passed to data path 132 in place of the data stored in memory array 120 at the selected address. As long as the power is maintained to DRAM 100, the write back to memory array 120 upon self refresh exit may be skipped.

FIG. 9 is a block diagram illustrating one embodiment of a portion 450 of DRAM 100 including error registers 160 for storing row addresses of tail bits for refreshing the tail bits more frequently. In this embodiment, the error detection process performed upon self refresh entry as previously described and illustrated with reference to FIGS. 2 and 3 is performed, except that the column addresses for failing memory array locations are excluded from error registers 160. Upon self refresh exit, no write back operation is performed.

Error registers 160 include row address registers 454. Error registers 160 are electrically coupled to row address counter 108 through signal path 456. For rows containing a tail bit as indicated by row addresses stored in row address registers 454, the refresh occurs more frequently than for row addresses not stored in row address registers 454. The more frequent refresh prevents the tail bits from failing. The row addresses stored in error registers 454 are compared with the row addresses provided by row address counter 108. If a match is found, the row is refreshed more frequently. For example, if one or more most significant bits are ignored in row address counter 108 when doing the compare, then the refresh can be performed more often.

Embodiments of the present invention provide a DRAM having ECC for detecting and correcting for tail bits without significantly impacting the self refresh exit timing. In one embodiment, upon self refresh exit, previously failing memory array locations are rechecked and corrected. In another embodiment, upon self refresh exit, previously corrected data is automatically written back to the failing memory array locations. In another embodiment, the error registers perform a redundancy function for replacing the failing memory array locations. In another embodiment, the failing memory array locations are refreshed more frequently to prevent future failures of the memory array locations. All these embodiments enable the refresh period to be extended, thereby reducing the refresh current. By reducing the refresh current, the overall power consumption of the memory is reduced.

What is claimed is:

1. A memory comprising:
a memory array for storing data;
a parity generation and error check circuit configured to receive data from the memory array and detect errors in the data; and
error registers configured for storing addresses of failing memory array locations detected by the parity generation and error check circuit upon self refresh entry for correcting the data stored in the failing memory array locations upon self refresh exit.

2. The memory of claim 1, wherein the error registers are further configured for storing corrected data for the failing memory array locations upon self refresh entry for writing the corrected data back to the failing memory array locations upon self refresh exit.

3. The memory of claim 1, wherein the parity generation and error check circuit is further configured to detect parity errors and correct detected parity errors at the addresses of failed memory array locations upon self refresh exit.

4. The memory of claim 1, further comprising:
an error address output circuit configured to output the addresses of failed memory array locations from the error registers based on a clock signal upon self refresh exit.

5. The memory of claim 1, further comprising:
a row address counter configured to provide a row address for each row of the memory array; and
a column address counter configured to provide a column address for each column of the memory array,
wherein the row address counter and the column address counter increment through row and column addresses of the memory array for generating parity information for the memory array.

6. A memory comprising:
a memory array;
a parity generation and error check circuit; and
error registers for storing addresses and corrected data of failed memory array locations detected by the parity generation and error check circuit upon self refresh entry for substituting the corrected data in place of data stored in the failed memory array locations in response to requests for data at addresses of failed memory array locations.

7. The memory of claim 6, further comprising:
a row address counter configured to provide a row address for each row of the memory array; and
a column address counter configured to provide a column address for each column of the memory array,
wherein the row address counter and the column address counter increment through row and column addresses of the memory array for generating parity information for the memory array.

8. A memory comprising:
a memory array for storing data;
a parity generation and error check circuit configured to receive data from the memory array and detect errors in the data; and
error registers configured for storing addresses of failing memory array locations detected by the parity generation and error check circuit upon self refresh entry for refreshing the failing memory array locations at a frequency greater than a refresh frequency for non-failing memory array locations.

9. The memory of claim 8, wherein the error registers are configured for storing row addresses of failing memory array locations.

10. The memory of claim 8, further comprising:
a row address counter configured to provide a row address for each row of the memory array; and
a column address counter configured to provide a column address for each column of the memory array,
wherein the row address counter and the column address counter increment through row and column addresses of the memory array for generating parity information for the memory array.

11. A dynamic random access memory comprising:
a memory array;
means for generating first parity information for the memory array upon self refresh entry;
means for comparing second parity information of the memory array to the first parity information after a first extended refresh period of the self refresh has elapsed to identify failing memory array locations;
means for storing information relating to the failed memory array locations; and
means for using the stored information to correct data stored in the failed memory array locations upon self refresh exit.

12. The memory of claim 11, wherein the means for using the stored information comprises means for clocking out row addresses and column addresses of failed memory array locations to correct data stored in the failed memory array locations.

13. A method for correcting errors in a memory, the method comprising:
generating first parity information for a memory array upon self refresh entry;
writing the first parity information to the memory array;
generating second parity information for the memory array after an extended refresh period has elapsed;
comparing the second parity information to the first parity information to identify first bit errors;
correcting the first bit errors and writing first corrected data back to the memory array based on the comparison of the second parity information to the first parity information;
storing locations of the first bit errors in error registers;
generating third parity information for locations stored in the error registers upon self refresh exit;
comparing the third parity information to the first parity information to identify second bit errors; and
correcting the second bit errors and writing second corrected data to the memory array based on the comparison of the third parity information to the first parity information.

14. The method of claim 13, wherein correcting the second bit errors and writing second corrected data to the memory array based on the comparison of the third parity information to the first parity information comprises correcting the second bit errors and writing second corrected data to the memory array based on the comparison of the third parity information to the first parity information in less than approximately 1 μs.

15. The method of claim 13, wherein generating first parity information comprises generating first parity information for the memory array in 64 bit segments.

16. The method of claim 13, wherein writing the second corrected data to the memory array based on the comparison of the third parity information to the first parity information comprises clocking the error registers to serially output a row address and a column address for each second bit error for writing the second corrected data to the memory array.

17. A method for correcting errors in a memory, the method comprising:
generating first parity information for a memory array upon self refresh entry;
writing the first parity information to the memory array;
generating second parity information for the memory array after an extended refresh period has elapsed;
comparing the second parity information to the first parity information to identify locations of failing bits;
storing the locations of failing bits in error registers based on the comparison;
writing corrected data for the failing bits to the error registers; and
writing the corrected data for the failing bits to the memory array upon self refresh exit.

18. The method claim 17, wherein writing the corrected data to the memory array comprises writing the corrected data to the memory array in less than approximately 1 μs.

19. The method of claim 17, wherein generating first parity information comprises generating first parity information for the memory array in 64 bit segments.

20. The method of claim 17, wherein writing the corrected data to the memory array upon self refresh exit comprises clocking the error registers to serially output a row address and a column address for each location of failing bits to write the corrected data to the memory array.

21. A method for correcting errors in a memory, the method comprising:
generating first parity information for a memory array upon self refresh entry;
writing the first parity information to the memory array;
generating second parity information for the memory array after an extended refresh period has elapsed;
comparing the second parity information to the first parity information to identify locations of failing bits;
storing the locations of failing bits in error registers based on the comparison;
writing corrected data for the failing bits to the error registers; and
substituting the corrected data in the error registers for data in locations of failing bits in the memory array.

22. The method of claim 21, wherein substituting the corrected data comprises comparing an address input to the locations of failing bits in the error registers.

23. The method of claim 21, wherein generating first parity information comprises generating first parity information for the memory array in 64 bit segments.

24. A method for correcting errors in a memory, the method comprising:
generating first parity information for a memory array upon self refresh entry;
writing the first parity information to the memory array;
generating second parity information for the memory array after an extended refresh period has elapsed;
comparing the second parity information to the first parity information to identify locations of failing bits;
storing the locations of failing bits in error registers based on the comparison;
correcting the failing bits and writing corrected data to the memory array based on the comparison; and
refreshing locations of failing bits more frequently than non-failing bits based on the locations of the failing bits stored in the error registers.

25. The method of claim 24, wherein storing locations of failing bits comprises storing row addresses of failing bits.

26. The method of claim 25, further comprising:
comparing the row addresses of failing bits to an output of a row address counter for refreshing locations of failing bits more frequently.

27. The method of claim 24, wherein refreshing locations of failing bits comprises refreshing locations of failing bits at least two times more frequently than non-failing bits.

28. The method of claim 24, wherein generating first parity information comprises generating first parity information for the memory array in 64 bit segments.
